(19) United States
(12) Patent Application Publication
(10) Pub. No.: US 2024/0103052 A1
(43) Pub. Date: Mar. 28, 2024

(54) NON-INTRUSIVE LOAD MONITORING METHOD AND DEVICE BASED ON PHYSICS-INFORMED NEURAL NETWORK

(71) Applicant: ZHEJIANG LAB, Hangzhou (CN)

(72) Inventors: GANG HUANG, HANGZHOU (CN); WEI HUA, HANGZHOU (CN); ZHOU ZHOU, HANGZHOU (CN)

(21) Appl. No.: 18/097,234

(22) Filed: Jan. 14, 2023

(30) Foreign Application Priority Data
Sep. 15, 2022 (CN) 202211118553.8

(51) Int. Cl. G01R 21/00; G06N 3/042; G06N 3/08

(52) U.S. Cl. CPC G01R 21/001; G06N 3/042; G06N 3/08

(57) ABSTRACT

The present invention relates to the cross field of smart grid and artificial intelligence, provides a non-intrusive load monitoring method and device based on physics-informed neural network, comprising the following steps: Step 1, obtaining a total load data and an equipment load data of a building in a certain period of time, and using a sliding window method to cut to construct a training data. Step 2, designing a deep learning neural network model to learn the equipment load characteristics contained in the total load data, and outputting the equipment load forecasting. Step 3, based on a physics-constrained learning framework, training the deep learning neural network model by iteratively optimizing the training loss to obtain a trained physics-informed neural network model. Step 4, monitoring the equipment's power consumption in the building according to the output results of the physics-informed neural network model. The present invention can fully extract the operation characteristics of electric equipment, and improve the accuracy of load identification without increasing additional cost.

### TECHNICAL FIELD

The present invention relates to the cross field of smart grid and artificial intelligence, in particular to a non-intrusive load monitoring method and device based on physics-informed neural network.

### DESCRIPTION OF RELATED ART

Accurate load identification is a prerequisite for achieving demand side management of smart grid, which can support the adjustment of balancing supply and demand of power grid, and the formulation of differentiated power sales strategy, etc., so as to promote the realization of the goal of “carbon peaking and carbon neutralization”. Different from the intrusive load monitoring technology with additional monitoring equipment, the non-intrusive load monitoring method can identify each independent power load and its working conditions in the total load data. In view of the limitations of the traditional non-intrusive load monitoring method based on feature construction and recognition in feature selection, the non-intrusive load monitoring method based on deep learning technology has been widely used. However, the existing deep learning methods ignore the importance of domain knowledge, which limits the accuracy of load monitoring. How to realize the load monitoring driven by knowledge-data collaboration is an important problem for the further development of demand side management and response work.

### SUMMARY OF THE INVENTION

The present invention aims to solve the above technical problems in demand side management of smart grid, and proposes a non-intrusive load monitoring method based on physics-informed neural network.

The technical scheme of the present invention is as follows:

A non-intrusive load monitoring method based on physics-informed neural network, comprising the following steps:
Step 1, obtaining a total load data and an equipment load data of a building in a certain period of time, and using a sliding window method to cut to construct a training data.
Step 2, designing a deep learning neural network model to learn the equipment load characteristics contained in the total load data, and outputting the equipment load forecasting.
Step 3, based on a physics-constrained learning framework, training the deep learning neural network model by iteratively optimizing the training loss to obtain a trained physics-informed neural network model.
Step 4, monitoring the equipment's power consumption in the building according to the output results of the physics-informed neural network model.

Further, step 1 is as follows:
Step 1.1, collecting an active power Pₜ_{₀}_{:t}_{ₙ} and a reactive power Qₜ_{₀}_{:t}_{ₙ} of the total load in the certain period of time, and an active power Pₜ_{₀}_{:t}_{ₙ}ⁱ and a reactive power Qₜ_{₀}_{:t}_{ₙ}ⁱ of the equipment load, and then obtaining a total load sample M=[Pₜ_{₀}_{:t}_{ₙ},Qₜ_{₀}_{:t}_{ₙ}] and an equipment load sample Lⁱ=[Pₜ_{₀}_{:t}_{ₙ}ⁱ,Qₜ_{₀}_{:t}_{ₙ}ⁱ], where i is the equipment number.
Step 1.2, using the sliding window with width w and step size l to cut M and Lⁱ, constructing the training data of the equipment Uⁱ={Mₜᵣₐᵢₙ, Lₜᵣₐᵢₙⁱ}, where,

Mₜᵣₐᵢₙ={[Pₜ_{ⱼ}_{:t}_{_{j+w}},Qₜ_{ⱼ}_{:t}_{_{j+w}}]|j=0, . . . ,n−w}

Lₜᵣₐᵢₙⁱ={[Pₜ_{ⱼ}_{:t}_{_{j+w}}ⁱ,Qₜ_{ⱼ}_{:t}_{_{j+w}}ⁱ]|j=0, . . . ,n−w}.

Further, step 2 is as follows:
Step 2.1, inputting the training data Uⁱ into the following deep learning neural network respectively:

h₀=Uⁱ

hₘ=Φ(Wₘ·hₘ₋₁+bₘ)
where, h₀ is the original input of the input layer of the constructed deep learning neural network, hₘ, wₘ and bₘ are respectively the output, weight and bias of the m th hidden layer of the neural network model, and Φ(⋅) is the activation function.
Step 2.2, designing the following output layer for learning:

Fⁱ=Ψ(W_{M}·h_{M}+b_{M})
where, Fⁱ=[\hat{P}ₜ_{ⱼ}_{:t}_{_{j+w}}ⁱ,\hat{Q}ₜ_{ⱼ}_{:t}_{_{j+w}}ⁱ] is the load forecasting of equipment i, h_{M} is the output of the last hidden layer of the network, W_{M} and b_{M} is the weight and bias of the output layer respectively, and WO is the activation function.

Further, the number of hidden layers of the neural network is 5, and the activation function is ReLU.

Further, the activation function adopts the Linear function.

Further, step 3 is as follows:
firstly, according to the physical relationship between powers, calculating a physical constraints violation loss lossₚⁱ of the deep learning neural network model corresponding to the equipment i, that is

$${loss}_{p}^{i} = {\sum }_{j = 0}^{n - w} \vert \sqrt{{( {\hat{P}}_{{t}_{j} : {t}_{j + w}}^{i} )}^{2} + {( {\hat{Q}}_{{t}_{j} : {t}_{j + w}}^{i} )}^{2}} - \sqrt{{( {P}_{{t}_{j} : {t}_{j + w}}^{i} )}^{2} + {( {Q}_{{t}_{j} : {t}_{j + w}}^{i} )}^{2}} \vert$$

then, calculating a prediction deviation loss loss_{f}ⁱ of the deep learning neural network model corresponding to the equipment i, that is

loss_{f}ⁱ=E(Fⁱ,Lₜᵣₐᵢₙⁱ)
where, E is the difference measurement function.
finally, calculating the training loss of the constrained physics-informed neural network model by weighted summation:

lossₜₒₜₐₗⁱ=loss_{f}ⁱ+ωₚ·lossₚⁱ
where, ωₚ is the weight coefficient of the physical constraints violation loss.

Further, step 4 is as follows:

Giving any time of the building as a starting point, an active power Pₜ_{ₖ}_{:t}_{_{j+w}} and a reactive power Qₜ_{ₖ}_{:t}_{_{j+w}} of the total load with width w, constructing a total load sample V=[Pₜ_{ₖ}_{:t}_{_{j+w}},Qₜ_{ₖ}_{:t}_{_{j+w}}]. Inputting V to the trained physics-informed neural network model, and the output result is the power consumption of each equipment load in the building, comprising the active power \hat{P}ₜ_{ₖ}_{:t}_{_{j+w}}ⁱ and the reactive power \hat{Q}ₜ_{ₖ}_{:t}_{_{j+w}}ⁱ.

A non-intrusive load monitoring device based on physics-informed neural network, comprising one or more processors for realizing the non-intrusive load monitoring method based on physics-informed neural network.

A computer readable storage medium on which a program is stored, when the program is executed by a processor, the non-intrusive load monitoring method based on physics-informed neural network is realized.

Comparing with the prior art, the present invention has the following advantages:
(1) In the present invention, the existing non-intrusive load monitoring method based on deep learning technology only uses active power as the input of the load monitoring model, which leads to the problem that the working characteristics of nonresistive loads cannot be accurately described. The active power and reactive power of load are used as the input at the same time innovatively. The constructed load monitoring model based on deep neural network can fully extract the operating characteristics of different types of loads, and improve the accuracy of load monitoring.
(2) In the present invention, in order to further ensure the validity and interpretability of load monitoring results, a model training framework based on physical constraints is used to train the constructed deep neural network model. The physical constraints between electrical quantities are embedded into the model training process by constructing the physical constraints violation loss, so that the trained model can not only accurately monitor the power consumption of equipment load, but also effectively improve the interpretability of load monitoring results in the physical level.

### BRIEF DESCRIPTION OF THE DRAWINGS

FIG. 1 is the flow chart of the non-intrusive load monitoring method based on physics-informed neural network of the present invention.

FIG. 2 is the structural diagram of the non-intrusive load monitoring device based on physics-informed neural network of the present invention.

### DETAILED DESCRIPTION OF THE INVENTION

The present invention is described in detail below in combination with the drawings and embodiments. It should be understood that the described embodiments only belong to a part of the present invention, not all embodiments, so the implementation of the invention should not be limited by the described embodiments, but should further understand the essence of the invention with the help of these embodiments, which can better serve those skilled in the art.

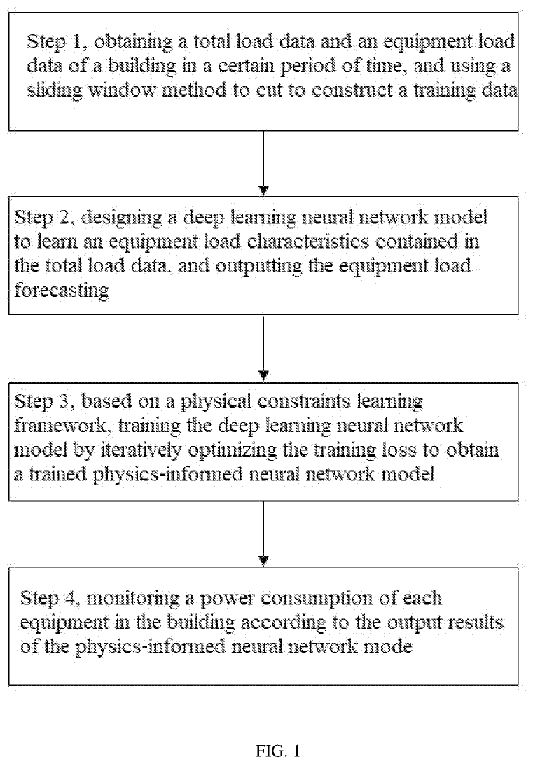

As shown in FIG. 1, the non-intrusive load monitoring method based on physics-informed neural network of the present invention comprises the following steps:
Step 1, obtaining a total load data and an equipment load data of a building in a certain period of time, and using a sliding window method to cut to construct a training data.
Step 1.1, collecting an active power Pₜ_{₀}_{:t}_{ₙ} and a reactive power Qₜ_{₀}_{:t}_{ₙ} of the total load in the certain period of time, and an active power Pₜ_{₀}_{:t}_{ₙ}ⁱ and a reactive power Qₜ_{₀}_{:t}_{ₙ}ⁱ of the equipment load, and then obtaining a total load sample M=[Pₜ_{₀}_{:t}_{ₙ},Qₜ_{₀}_{:t}_{ₙ}] and an equipment load sample Lⁱ=[Pₜ_{₀}_{:t}_{ₙ}ⁱ,Qₜ_{₀}_{:t}_{ₙ}ⁱ], where i is the equipment number.

In this embodiment, a total of 78 days of load data of a building are collected, comprising independent equipment loads, the sampling frequency is 5 seconds. In this embodiment, the start time of 78 days is set as time 1, and the end time is set as time 1347840, that is, t₀=1, tₙ=1347840, the load data obtained can be expressed as: the active power P_{1:1347840} and the reactive power Q_{1:1347840} of the total load, the active power P_{1:1347840}ⁱ and the reactive power Q_{1:1347840}ⁱ of each independent equipment load, where the equipment number i∈{1, . . . , 10}. Then, the total load sample M=[P_{1:1347840},Q_{1:1347840}] and each independent load sample Lⁱ=[P_{1:1347840}ⁱ,Q_{1:1347840}ⁱ] can be obtained. In order to eliminate the influence of acquisition error on model training, in this embodiment, the value of samples with the active power less than zero in the total load and each independent load sample is set to zero.
Step 1.2, using the sliding window with width w and step size l to cut M and Lⁱ, constructing the training data of the equipment Uⁱ={Mₜᵣₐᵢₙ, Lₜᵣₐᵢₙⁱ}, where,

Mₜᵣₐᵢₙ={[Pₜ_{ⱼ}_{:t}_{_{j+w}},Qₜ_{ⱼ}_{:t}_{_{j+w}}]|j=0, . . . ,n−w}

Lₜᵣₐᵢₙⁱ={[Pₜ_{ⱼ}_{:t}_{_{j+w}}ⁱ,Qₜ_{ⱼ}_{:t}_{_{j+w}}ⁱ]|j=0, . . . ,n−w}.

In this embodiment, using the sliding window with width 599 and step size 1 to cut M and Lⁱ, then the constructed training data can be further expressed as:

Mₜᵣₐᵢₙ={[Pₜ_{ⱼ}_{:t}_{ⱼ₊₅₉₉},Qₜ_{ⱼ}_{:t}_{ⱼ₊₅₉₉}]|j=0, . . . ,1347241}

Lₜᵣₐᵢₙⁱ={[Pₜ_{ⱼ}_{:t}_{ⱼ₊₅₉₉}ⁱ,Qₜ_{ⱼ}_{:t}_{ⱼ₊₅₉₉}ⁱ]|j=0, . . . ,1347241}
Step 2, designing a deep learning neural network model to learn the equipment load characteristics contained in the total load data, and outputting the equipment load forecasting.
Step 2.1, inputting the training data Uⁱ into the following deep learning neural network respectively:

h₀=Uⁱ

hₘ=Φ(Wₘ·hₘ₋₁+bₘ)

where, h₀ is the original input of the input layer of the constructed deep learning neural network, hₘ, Wₘ and bₘ are respectively the output, weight and bias of the m th hidden layer of the neural network model, and Φ(⋅) is the activation function.

In this embodiment, the number of hidden layers of the neural network is 5, and the activation function Φ(⋅) is ReLU, then the deep learning neural network used can be expressed as:

h₀=Uⁱ

hₘ=ReLU(Wₘ·hₘ₋₁+bₘ)
Step 2.2, designing the following output layer for learning:

Fⁱ=Ψ(W_{M}·hₘ+b_{M})
where, Fⁱ=[\hat{P}ₜ_{ⱼ}_{:t}_{_{j+w}}ⁱ,\hat{Q}ₜ_{ⱼ}_{:t}_{_{j+w}}ⁱ] is the load forecasting of equipment i, h_{M} is the output of the last hidden layer of the network, W_{M} and b_{M} is the weight and bias of the output layer respectively, and Ψ(⋅) is the activation function.

In this embodiment, the activation function Ψ(⋅) is Linear, the network output layer can be expressed as:

Fⁱ=Linear(W_{M}·h_{M}+b_{M})
the network outputs the load forecasting of independent equipment load Fⁱ==[\hat{P}_{1:1347840}ⁱ,\hat{Q}_{1:1347840}ⁱ].
Step 3, based on a physics-constrained learning framework, training the deep learning neural network model by iteratively optimizing the training loss to obtain a trained physics-informed neural network model.

Firstly, according to the physical relationship between powers, calculating a physical constraints violation loss lossₚⁱ of the deep learning neural network model corresponding to the equipment i, that is

$${loss}_{p}^{i} = {\sum }_{j = 0}^{n - w} \vert \sqrt{{( {\hat{P}}_{{t}_{j} : {t}_{j + w}}^{i} )}^{2} + {( {\hat{Q}}_{{t}_{j} : {t}_{j + w}}^{i} )}^{2}} - \sqrt{{( {P}_{{t}_{j} : {t}_{j + w}}^{i} )}^{2} + {( {Q}_{{t}_{j} : {t}_{j + w}}^{i} )}^{2}} \vert$$

In this embodiment, the physical constraints violation loss lossₚ can be expressed as:

$${loss}_{p}^{i} = {\sum }_{j = 0}^{1347241} \vert \sqrt{{( {\hat{P}}_{{t}_{j} : {t}_{j + 599}}^{i} )}^{2} + {( {\hat{Q}}_{{t}_{j} : {t}_{j + 599}}^{i} )}^{2}} - \sqrt{{( {P}_{{t}_{j} : {t}_{j + 599}}^{i} )}^{2} + {( {Q}_{{t}_{j} : {t}_{j + 599}}^{i} )}^{2}} \vert$$

Then, calculating a prediction deviation loss loss_{f}ⁱ of the deep learning neural network model corresponding to the equipment i, that is

loss_{f}ⁱ=E(Fⁱ,Lₜᵣₐᵢₙⁱ)
where, E is the difference measurement function.

In this embodiment, the mean square error (MSE) is adopted as the difference measurement function E, the prediction deviation loss function can be further expressed as:

$${loss}_{f}^{i} = {\sum }_{j = 1}^{1347241} {( {\hat{P}}_{{t}_{j} : {t}_{j + 599}}^{i} - {P}_{{t}_{j} : {t}_{j + 599}}^{i} )}^{2}$$

Finally, calculating the training loss of the constrained physics-informed neural network model by weighted summation:

lossₜₒₜₐₗⁱ=loss_{f}ⁱ+ωₚ·lossₚⁱ
where, ωₚ is the weight coefficient of the physical constraints violation loss.

In this embodiment, the weight coefficient of the physical constraints violation loss ωₚ=0.1, the training loss of the model can be expressed as:

$${loss}_{total}^{i} = {\sum }_{j = 1}^{1347241} {( {\hat{P}}_{{t}_{j} : {t}_{j + 599}}^{i} - {P}_{{t}_{j} : {t}_{j + 599}}^{i} )}^{2} + 0.1 \times {\sum }_{j = 0}^{1347241} \vert \sqrt{{( {\hat{P}}_{{t}_{j} : {t}_{j + 599}}^{i} )}^{2} + {( {\hat{Q}}_{{t}_{j} : {t}_{j + 599}}^{i} )}^{2}} - \sqrt{{( {P}_{{t}_{j} : {t}_{j + 599}}^{i} )}^{2} + {( {Q}_{{t}_{j} : {t}_{j + 599}}^{i} )}^{2}} \vert$$

the constructed deep learning neural network model is trained by iteratively optimizing the above training loss function, and the batch_size is 1000, the learning rate is 0.001, and the number of iterations is 50.
Step 4, monitoring the equipment's power consumption in the building according to the output results of the physics-informed neural network model.

Giving any time of the building as a starting point, an active power Pₜ_{ₖ}_{:t}_{_{k+w}} and a reactive power Qₜ_{ₖ}_{:t}_{_{k+w}} of the total load with width w, constructing a total load sample V=[Pₜ_{ₖ}_{:t}_{_{k+w}},Qₜ_{ₖ}_{:t}_{_{k+w}}]. Inputting V to the trained physics-informed neural network model, and the output result is the power consumption of each equipment load in the building, comprising the active power \hat{P}ₜ_{ₖ}_{:t}_{_{k+w}}ⁱ and the reactive power \hat{Q}ₜ_{ₖ}_{:t}_{_{k+w}}ⁱ.

In this embodiment, Giving the time tₖ=1347841 of the building as the starting point, the active power P_{1347841:1348440} and the reactive power Q_{1347841:1348440} with width 599 of the total load, constructing the total load sample V=[P_{1347841:1348440},Q_{1347841:1348440}]. Inputting V to the trained physics-informed neural network model, and the output result is the power consumption of each equipment load in the building, comprising the active power \hat{P}_{1347841:1348440}ⁱ and the reactive power \hat{Q}_{1347841:1348440}.

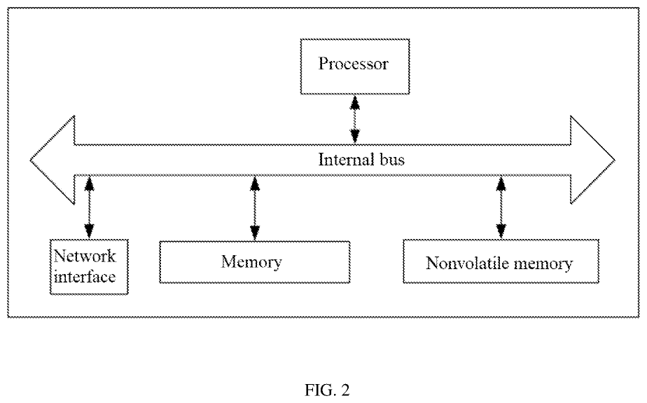

As shown in FIG. 2, a non-intrusive load monitoring device based on physics-informed neural network provided by the present invention, comprising one or more processors for realizing the non-intrusive load monitoring method based on physics-informed neural network.

The embodiment of the non-intrusive load monitoring device based on the physics-informed neural network of the present invention can be applied to any device with data processing capability, which can be a device or equipment such as a computer. The device embodiments can be realized by software, hardware or combination of software and hardware. Taking software implementation as an example, as a logical device, it is formed by reading the corresponding computer program instructions in the nonvolatile memory into the memory through the processor of any device with data processing capability. On the hardware level, as shown in FIG. 2, it is a hardware structure diagram of any device with data processing capability where the non-intrusive load monitoring device based on the physics-informed neural network of the present invention. In addition to the processor, memory, network interface and non-volatile memory shown in FIG. 2, any device with data processing capability in the embodiment can also include other hardware according to the actual function of any device with data processing capability, which will not be repeated.

The realization process of the function and effect of each unit in the above device is detailed in the realization process of the corresponding steps in the above method, and will not be repeated here.

For the device embodiment, since it basically corresponds to the method embodiment, please refer to the partial description of the method embodiment for relevant points. The device embodiments described above are only schematic, in which the units described as separate units can be or can not be physically separated, and the units displayed as units can be or cannot be physical units, that is, they can be located in one place, or they can be distributed to multiple network units. Some or all of the modules can be selected according to the actual needs to realize the purpose of the scheme of the invention. Ordinary technicians in the art can understand and implement without paying creative labor.

This embodiment of the present invention also provides a computer readable storage medium on which a program is stored, when the program is executed by a processor, the non-intrusive load monitoring method based on physics-informed neural network of this embodiment is realized.

The computer readable storage medium may be an internal storage unit of any device with data processing capability described in any of the aforementioned embodiments, such as a hard disk or a memory. The computer readable storage medium may be an external storage device, for example, a plug-in hard disk, a smart media card (SMC), a SD card, a flash card, etc. equipped on the device. Furthermore, the computer readable storage medium can also include both an internal storage unit of any device with data processing capability and an external storage device. The computer readable storage medium is used to store the computer program and other programs and data required by any device with data processing capability, and can also be used to temporarily store the data that has been output or will be output.

The above description is only a preferred implementation case of the invention and does not limit the invention in any form. Although the implementation process of the invention has been described in detail above, for those who are familiar with the art, they can still modify the technical solutions recorded in the above examples, or replace some of the technical features equally. Any modification and equivalent replacement made within the spirit and principle of the invention shall be included in the protection scope of the invention.

1. A non-intrusive load monitoring method based on physics-informed neural network, wherein, comprising the following steps:
Step 1, obtaining a total load data and an equipment load data of a building in a certain period of time, and using a sliding window method to cut to construct a training data;
Step 2, designing a deep learning neural network model to learn the equipment load characteristics contained in the total load data, and outputting the equipment load forecasting;
Step 3, based on a physics-constrained learning framework, training the deep learning neural network model by iteratively optimizing the training loss to obtain a trained physics-informed neural network model; and
Step 4, monitoring the equipment's power consumption in the building according to the output results of the physics-informed neural network model;
wherein, the step 1 is as follows:
Step 1.1, collecting an active power Pₜ_{₀}_{:t}_{ₙ} and a reactive power Qₜ_{₀}_{:t}_{ₙ} of the total load in the certain period of time, and an active power Pₜ_{₀}_{:t}_{ₙ}ⁱ and a reactive power Qₜ_{₀}_{:t}_{ₙ}ⁱ of the equipment load, and then obtaining a total load sample M=[Pₜ_{₀}_{:t}_{ₙ},Qₜ_{₀}_{:t}_{ₙ}] and an equipment load sample Lⁱ=[Pₜ_{₀}_{:t}_{ₙ}ⁱ,Qₜ_{₀}_{:t}_{ₙ}ⁱ], where i is the equipment number;
Step 1.2, using the sliding window with width w and =step size l to cut M and Lⁱ, constructing the training data Uⁱ={Mₜᵣₐᵢₙ,Lₜᵣₐᵢₙⁱ} of the equipment i, where,
Mₜᵣₐᵢₙ={[Pₜ_{ⱼ}_{:t}_{_{j+w}},Qₜ_{ⱼ}_{:t}_{_{j+w}}]|j=0, . . . ,n−w}
Lₜᵣₐᵢₙⁱ={[Pₜ_{ⱼ}_{:t}_{_{j+w}}ⁱ,Qₜ_{ⱼ}_{:t}_{_{j+w}}ⁱ]|j=0, . . . ,n−w};
wherein, the step 2 is as follows:
Step 2.1, inputting the training data Uⁱ into the following deep learning neural network respectively:
h₀=Uⁱ
hₘ=Φ(Wₘ·hₘ₋₁+bₘ)
where, h₀ is the original input of the input layer of the constructed deep learning neural network, hₘ, Wₘ and bₘ are respectively the output, weight and bias of the m th hidden layer of the neural network model, and Φ(⋅) is the activation function;
Step 2.2, designing the following output layer for learning:
Fⁱ=Ψ(W_{M}·h_{M}+b_{M})
where, Fⁱ=[\hat{P}ₜ_{ⱼ}_{:t}_{_{j+w}}ⁱ,\hat{Q}ₜ_{ⱼ}_{:t}_{_{j+w}}] is the load forecasting of equipment i, h_{M} is the output of the last hidden layer of the network, W_{M} and b_{M} is the weight and bias of the output layer respectively, and Ψ(⋅) is the activation function;
wherein, the step 3 is as follows:
firstly, according to the physical relationship between powers, calculating a physical constraints violation loss lossₚⁱ of the deep learning neural network model corresponding to the equipment i that is
$${loss}_{p}^{i} = {\sum }_{j = 0}^{n - w} \vert \sqrt{{( {\hat{P}}_{{t}_{j} : {t}_{j + w}}^{i} )}^{2} + {( {\hat{Q}}_{{t}_{j} : {t}_{j + w}}^{i} )}^{2}} - \sqrt{{( {P}_{{t}_{j} : {t}_{j + w}}^{i} )}^{2} + {( {Q}_{{t}_{j} : {t}_{j + w}}^{i} )}^{2}} \vert ;$$
then, calculating a prediction deviation loss loss_{f}ⁱ of the deep learning neural network model corresponding to the equipment i that is
loss_{f}ⁱ=E(Fⁱ,Lₜᵣₐᵢₙⁱ);
where, E is the difference measurement function;
finally, calculating the training loss of the constrained physics-informed neural network model by weighted summation:
lossₜₒₜₐₗⁱ=loss_{f}ⁱ+ωₚ·lossₚⁱ
where, ωₚ is the weight coefficient of the physical constraints violation loss.

2-3. (canceled)

4. The non-intrusive load monitoring method based on physics-informed neural network according to claim 1, wherein, the number of hidden layers of the neural network is 5, and the activation function is ReLU.

5. The non-intrusive load monitoring method based on physics-informed neural network according to claim 1, wherein, the activation function adopts the Linear function.

6. (canceled)

7. The non-intrusive load monitoring method based on physics-informed neural network according to claim 1, wherein, step 4 is as follows:
giving any time of the building as a starting point, an active power Pₜ_{ₖ}_{:t}_{_{k+w}} and a reactive power Qₜ_{ₖ}_{:t}_{_{k+w}} of the total load with width w, constructing a total load sample V=[Pₜ_{ₖ}_{:t}_{_{k+w}},Qₜ_{ₖ}_{:t}_{_{k+w}}]; inputting V to the trained physics-informed neural network model, and the output result is the power consumption of each equipment load in the building, comprising the active power \hat{P}ₜ_{ₖ}_{:t}_{_{k+w}}ⁱ and the reactive power \hat{Q}ₜ_{ₖ}_{:t}_{_{k+w}}ⁱ.

8. A non-intrusive load monitoring device based on physics-informed neural network, comprising one or more processors for realizing the non-intrusive load monitoring method based on physics-informed neural network according to claim 1.

9. A computer readable storage medium on which a program is stored, when the program is executed by a processor, the non-intrusive load monitoring method based on physics-informed neural network according to claim 1.
